(19) United States
(12) Patent Application Publication
(10) Pub. No.: US 2026/0279927 A1
(43) Pub. Date: Sep. 17, 2026

(54) BATTERY MANAGEMENT SYSTEM AND METHOD FOR OPERATING SAME

(71) Applicants: HYUNDAI MOTOR COMPANY, SEOUL (KR); KIA CORPORATION, SEOUL (KR)

(72) Inventor: Jonghyun Park, Hwaseong-si (KR)

(73) Assignees: HYUNDAI MOTOR COMPANY, SEOUL (KR); KIA CORPORATION, SEOUL (KR)

(21) Appl. No.: 19/313,858

(22) Filed: Aug. 28, 2025

(30) Foreign Application Priority Data
Mar. 11, 2025 (KR) 10-2025-0031061

(51) Int. Cl. H01M 10/42; G01R 31/382; G01R 31/396; H01M 10/48; H02J 7/00; H04W 76/14

(52) U.S. Cl. CPC H01M 10/425; G01R 31/382; G01R 31/396; H01M 10/482; H02J 7/40; H02J 7/52; H04W 76/14; H01M 2010/4271; H01M 2010/4278; H01M 2220/20

(57) ABSTRACT

The present disclosure provides a battery management system and a method for operating the same. A battery management system may include a plurality of battery modules. Each battery module may include a plurality of battery cells. The system may include a cell monitoring unit to monitor a corresponding battery module and generate battery module information including state of charge (SOC) information. The system may include at least one wireless communication unit provided in a corresponding monitoring unit and configured to support wireless communication by consuming power of the corresponding battery module. The system also may include a control unit configured to control at least one cell monitoring unis and a corresponding wireless communication unit based on the battery module information. The control unit is configured to control the wireless communication unit to consume power of the battery module to perform cell balancing for the battery module.

### CROSS-REFERENCE TO RELATED APPLICATION(S)

This present application claims the benefit of priority to Korean Patent Application No. 10-2025-0031061, filed on Mar. 11, 2025, in the Korean Intellectual Property Office, the entire disclosure of which is incorporated herein by reference.

### TECHNICAL FIELD

The present disclosure relates to a battery management system and a method for operating the battery management system, and more particularly, to a battery management system that resolves voltage imbalance among battery cells.

### BACKGROUND

The battery management system (BMS) has become a core technology for monitoring a state of a battery and ensuring safe and efficient operation in various applications including electric vehicles. In particular, in environments where high-voltage batteries are used, it is useful to maintain a uniform state of each battery cell. Cell balancing technology may be used for maintaining the uniform state.

In existing battery management systems, a passive cell balancing method may be considered. In the passive cell balancing method, a battery management unit (BMU) and a cell monitoring unit (CMU) are fully activated to perform cell balancing, which causes the entire system to wake up, resulting in unnecessary power consumption. Additionally, since the passive cell balancing method consumes power through resistive elements, it is limited in that equalizing state of charge (SOC) differences among cells takes considerable time.

In existing battery modules, a technique for monitoring battery status based on wireless communication functionality is utilized. However, since the wireless communication functionality consumes power of the battery cells within the module, unnecessary power consumption occurs.

This Background section is for enhancement of understanding of the background of the disclosure, and should not be taken as acknowledgement that this section corresponds to art already known to those skilled in the art.

### SUMMARY

The following summary presents a simplified summary and is not an extensive overview and is not intended to identify key or critical elements.

The present disclosure is directed to providing a battery management system and a method for operating the same, which may perform battery cell balancing by causing each of a plurality of wireless communication units to consume power of a corresponding battery module.

Further, the present disclosure is directed to providing a battery management system and a method for operating the same, which, based on a specification (e.g., requirement) for cell balancing of the specific battery module, may perform cell balancing independently for a (e.g., specific) battery module without waking up the entire system.

Still further, the present disclosure is directed to providing a battery management system and a method for operating the same, which may perform cell balancing more quickly than a passive cell balancing method using (e.g., only) balancing resistors.

Aspects of the present disclosure are not limited to those mentioned above, and other aspects and improvements not mentioned above will be understood from the following description, and become more apparent from the exemplary embodiments. Moreover, aspects of the present disclosure may be realized by the present disclosure and the claims.

An aspect of the present disclosure may provide a battery management system. The battery management system may include a plurality of battery modules with each battery module including a plurality of battery cells, and a plurality of cell monitoring units with each monitoring unit configured to monitor a corresponding (e.g., one) battery module of the plurality of battery modules and generate battery module information for the corresponding battery module. The battery module information may include state of charge (SOC) information of the corresponding battery module. The battery management system may further include a plurality of wireless communication unit with each wireless communication unit provided in a corresponding (e.g., one of the plurality of cell monitoring units) cell monitoring unit and configured to support wireless communication by consuming power of the corresponding battery module monitored by the corresponding cell monitoring unit. The battery management system may include a control unit configured to control at least one of the plurality of cell monitoring units and its corresponding wireless communication unit based on the battery module information, wherein the control unit is configured to control at least one wireless communication unit corresponding to at least one battery module such that the wireless communication unit consumes power of the battery module, thereby performing cell balancing for the battery module.

The control unit may be configured to determine at least one battery module having a SOC deviation that exceeds a predetermined SOC deviation threshold based on a SOC deviation for each of the plurality of battery modules.

The battery module information may include SOC information of each of the plurality of battery cells included in each of the plurality of battery modules, and the control unit may be configured to determine a duration of the cell balancing based on SOC deviations of the plurality of battery cells included in each of the at least one determined battery module.

Another aspect of the present disclosure may provide a method for operating a battery management system. The method may include, by each of a plurality of cell monitoring units, monitoring a corresponding (e.g., one) battery module of the plurality of battery modules and generating battery module information for the corresponding battery module. The battery module information may include state of charge (SOC) information of the corresponding battery module. The method may include a plurality of wireless communication units, each wireless communication unit provided in a corresponding (e.g., one) cell monitoring unit of the plurality of cell monitoring units, performing wireless communication by consuming power of the corresponding battery module monitored by the corresponding cell monitoring unit. A control unit may be configured to control at least one of the plurality of cell monitoring units and its corresponding wireless communication unit based on the battery module information. The method may include controlling, via the control unit, at least one wireless communication unit corresponding to at least one battery module such that the wireless communication unit consumes power of the battery module, thereby performing cell balancing for the battery module.

The controlling may include determining at least one battery module having a SOC deviation that exceeds a predetermined SOC deviation threshold based on a SOC deviation for each of the plurality of battery modules.

The battery module information may include SOC information of each of the plurality of battery cells included in each of the plurality of battery modules, and the controlling may further include determining a duration of the cell balancing based on SOC deviations of the plurality of battery cells included in each of the at least one determined battery module.

According to example embodiments of the present disclosure, it is possible to perform cell balancing through power consumption by the wireless communication units.

In addition, according to example embodiments of the present disclosure, based on a specification (e.g., requirement) for cell balancing of a specific battery module, it is possible to perform cell balancing independently for (e.g., only) the battery module that may benefit from (e.g., requires) cell balancing without waking up the entire system.

Further, according to example embodiments of the present disclosure, based on a large difference in state of charge (SOC) between battery cells, it is possible to perform cell balancing more rapidly than a passive cell balancing method that uses (e.g., only) balancing resistors.

### BRIEF DESCRIPTION OF THE DRAWINGS

The foregoing and other aspects, features, and advantages, as well as the following detailed description of the embodiments, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a block diagram illustrating a configuration of a battery management system according to an example embodiment of the present disclosure.

FIG. 2 is a flowchart illustrating a method for operating a battery management system according to an example embodiment of the present disclosure.

FIG. 3 is a flowchart illustrating a method for operating a battery management system based on deactivation of an ignition device according to an example embodiment of the present disclosure.

FIG. 4 is a diagram illustrating a method for operating a battery management system based on deactivation of an ignition device according to an example embodiment of the present disclosure.

FIG. 5 is a flow chart illustrating a method for operating a battery management system based on deactivation of an ignition device according to an example embodiment of the present disclosure.

FIG. 6 is a diagram illustrating a method for operating a battery management system based on deactivation of an ignition device according to an example embodiment of the present disclosure.

FIG. 7 is a flowchart illustrating a method for operating a battery management system based on activation of an ignition device according to an example embodiment of the present disclosure.

FIG. 8 is a diagram illustrating a method for operating a battery management system based on activation of an ignition device according to an example embodiment of the present disclosure.

### DETAILED DESCRIPTION

Hereinafter, example embodiments disclosed in the present document will be described in detail with reference to the accompanying drawings. Like reference numerals designate like elements, and redundant descriptions thereof will be omitted. Further, such as “module” and a “unit”, suffixes for components used in the following description are given or mixed and used by considering easiness in preparing a specification and may not have a meaning or role distinguished from each other in themselves. In addition, in describing an example embodiment disclosed in the present document, if it is determined that a detailed description incorporated herein unnecessarily obscures the gist of the example embodiment, the detailed description thereof may be omitted. Furthermore, it should be understood that the appended drawings are intended to help understand example embodiments disclosed in the present document and do not limit the technical principles and scope of the present disclosure; rather, it should be understood that the appended drawings include modifications, equivalents or substitutes described by the technical principles and belonging to the technical scope of the present disclosure.

Although the terms first, second, and the like, may be used herein to describe various elements, these elements should not be limited by these terms. These terms are generally used to distinguish one element from another.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present.

The term “unit” or “module” used in this specification signifies a (e.g., one) unit that processes at least one function or operation, and may be realized by hardware, software, or a combination thereof. The operations of the method or the functions described in connection with the forms disclosed herein may be embodied directly in a hardware or a software module executed by a processor, or in a combination thereof. For example, the “unit” or “module” may include a memory storing computer-executable instructions and at least one processor configured to access the memory and execute the instructions.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

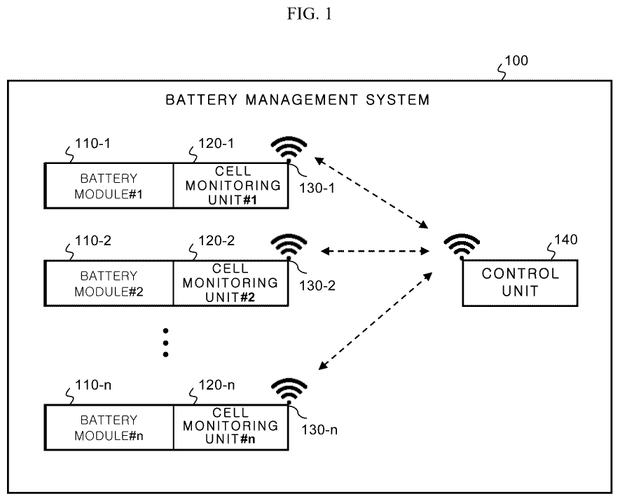

Hereinafter, a battery management system and a method for operating the same according to example embodiments of the present disclosure will be described in detail with reference to FIGS. 1 to 8.

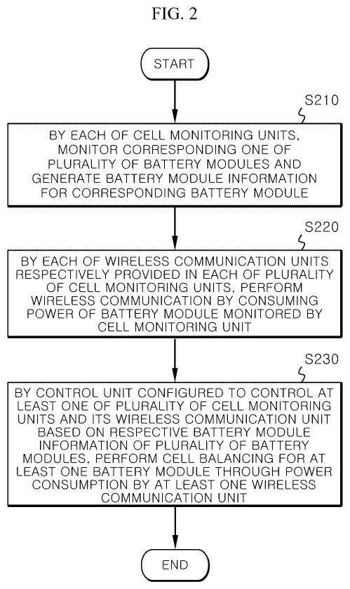

FIG. 1 is a block diagram illustrating a configuration of a battery management system according to an example embodiment of the present disclosure, and FIG. 2 is a flowchart illustrating a method for operating a battery management system according to an example embodiment of the present disclosure.

Referring to FIG. 1, a battery management system 100 according to an example embodiment of the present disclosure may include a plurality of battery modules 110-1, 110-2, . . . , 110-n, a plurality of cell monitoring units (CMUs) 120-1, 120-2, . . . , 120-n, a plurality of wireless communication units 130-1, 130-2, . . . , 130-n, a control unit 140, and other components associated with battery management.

Each of the battery modules 110-1, 110-2, . . . , 110-n may be a battery assembly including one or more battery cells connected in series or in parallel.

For example, the battery modules 110-1, 110-2, . . . , 110-n may include, but are not limited to, lithium-ion battery cells, lithium polymer battery cells, and all-solid-state battery cells. The voltage and capacity of the battery modules 110-1, 110-2, . . . , 110-n may vary depending on the connection method.

Each of the cell monitoring units 120-1, 120-2, . . . , 120-n may monitor a corresponding (e.g., one) battery module, of the plurality of battery modules, and generate battery module information for the corresponding battery module (see S210 of FIG. 2).

For example, each of the cell monitoring units 120-1, 120-2, . . . , 120-n may measure state information such as voltage, current, and temperature of a corresponding (e.g., one) battery module, evaluate the state of charge (SOC) of each of a plurality of battery cells included in the corresponding battery module, the SOC and the state of health (SOH) of the corresponding battery module, and other similar parameters and generate battery module information. In addition, each cell monitoring unit may cooperate with a protection circuit, as needed, to (e.g., safely) manage the battery module.

The wireless communication units 130-1, 130-2, . . . , 130-n may be respectively provided in the cell monitoring units 120-1, 120-2, . . . , 120-n to support wireless communication (see S220 of FIG. 2).

For example, each of the wireless communication units 130-1, 130-2, . . . , 130-n may transmit and receive information to and from the corresponding (e.g., one) cell monitoring unit 120-1, 120-2, . . . , 120-n and the control unit 140 using communication protocols such as Bluetooth, Wi-Fi, and low-power wide-area network (LPWAN). Accordingly, the battery management system may be configured without wiring. Each of the wireless communication units 130-1, 130-2, . . . , 130-n may operate by consuming power of the corresponding battery module monitored by the corresponding cell monitoring unit (CMU) 120-1, 120-2, . . . , 120-n, and may perform cell balancing for the corresponding battery module through such power consumption.

The control unit 140 may control at least one of the plurality of cell monitoring units 120-1, 120-2, . . . , 120-n and its wireless communication unit 130-1, 130-2, . . . , 130-n based on respective battery module information of the plurality of battery modules (see S230 of FIG. 2).

For example, the control unit 140 may be implemented as an independent hardware module, such as a battery management unit (BMU), in the battery management system 100, or may be implemented as software included in the battery management system 100, the cell monitoring units 120-1, 120-2, . . . , 120-n, or the BMU. The control unit 140 may receive battery module information from the plurality of cell monitoring units 120-1, 120-2, . . . , 120-n and, based on the received battery module information, may control the plurality of cell monitoring units, the plurality of wireless communication units, and other associated components to perform a specific operation.

The control unit 140 may control at least one wireless communication unit corresponding to at least one battery module such that the wireless communication unit consumes power of the battery module, thereby performing cell balancing for the battery module (see S230 of FIG. 2).

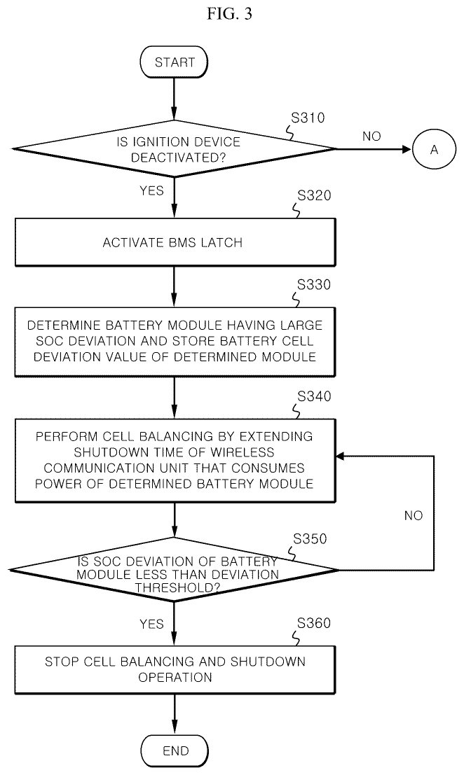

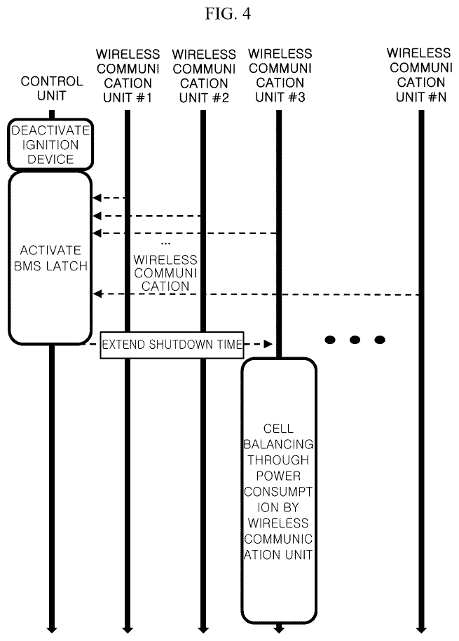

FIG. 3 is a flowchart illustrating a method for operating a battery management system based on deactivation of an ignition device according to an example embodiment of the present disclosure, and FIG. 4 is a diagram illustrating a method for operating a battery management system based on deactivation of an ignition device according to an example embodiment of the present disclosure.

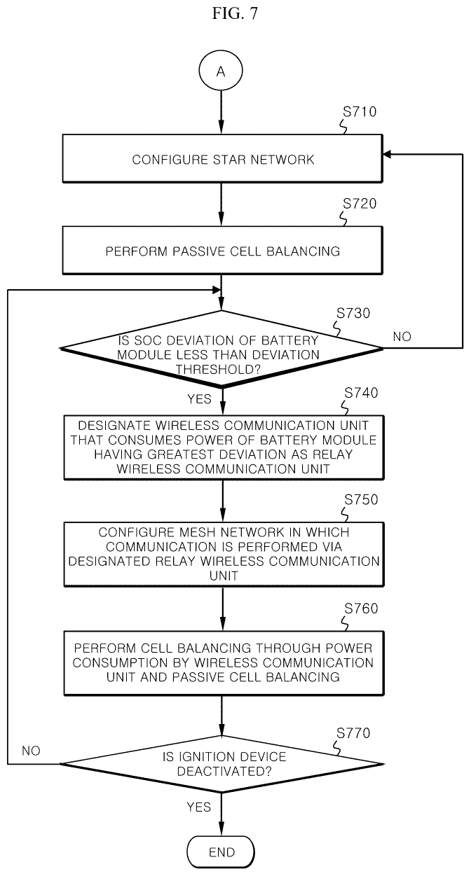

Referring to FIGS. 3 and 4, based on deactivation of the ignition device—for example, a state in which battery-powered electrical loads are turned off, such as when the ignition of an electric vehicle is turned off (see S310 of FIG. 3), if the determination at S310 is “no,” the flow proceeds to the step indicated by “A” in the circle, which corresponds to the process shown in FIG. 7 starting from S710—a latch of the battery management system may be activated (see S320 of FIG. 3). Each of the cell monitoring units 120-1, 120-2, . . . , 120-n may monitor a corresponding (e.g., one) battery module of the battery modules and transmit battery module information including state of charge (SOC) of the corresponding battery modules to the control unit. The control unit 140 may determine a SOC deviation for each of the plurality of battery modules 110-1, 110-2, . . . , 110-n based on the received battery module information, and may determine at least one battery module having a large SOC deviation, for example, a deviation exceeding a predetermined SOC deviation threshold. The control unit 140 may store SOC deviation values to determine a cell balancing time. For example, each stored SOC deviation may be a value obtained by subtracting the lowest SOC among the SOCs of the battery cells in each of the plurality of battery modules from the average SOC of the corresponding battery module (see S330 of FIG. 3). The control unit 140 may extend a shutdown time of the wireless communication unit that consumes power of the corresponding battery module determined as described above, so as to perform cell balancing through power consumption by the wireless communication unit together with passive cell balancing (see S340 of FIG. 3). The control unit 140 may stop the cell balancing and shut down the operation of the wireless communication unit based on the SOC deviation of the corresponding battery module being less than a predetermined SOC deviation threshold as a result of the cell balancing for the corresponding battery module (see S350 and S360 of FIG. 3).

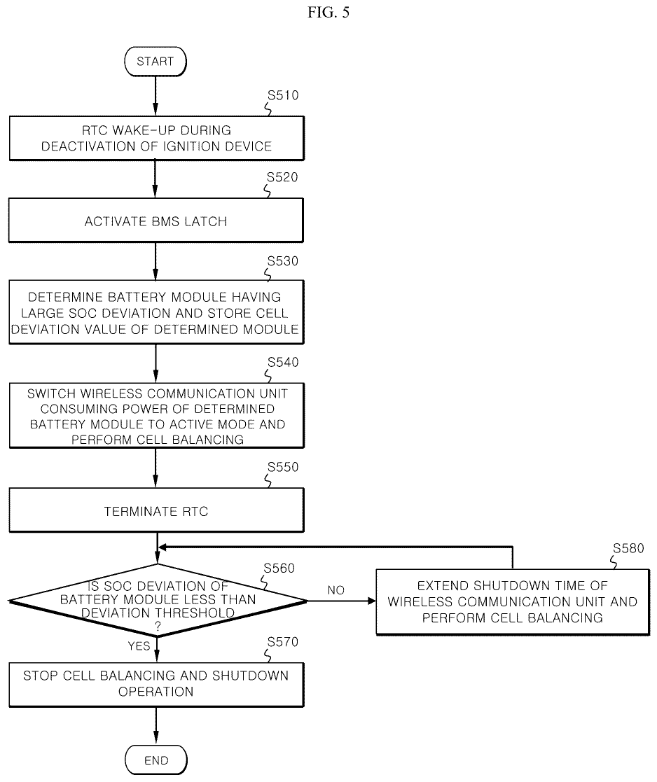

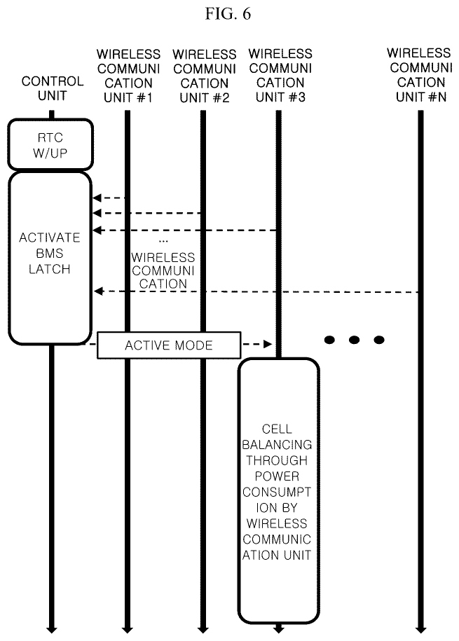

FIG. 5 is a flowchart illustrating a method for operating a battery management system based on deactivation of an ignition device according to an example embodiment of the present disclosure, and FIG. 6 is a diagram illustrating a method for operating a battery management system based on deactivation of an ignition device according to an example embodiment of the present disclosure.

Referring to FIGS. 5 and 6, during deactivation of the ignition device—for example, a state in which battery-powered electrical loads are turned off, such as when the vehicle is parked and not in operation (see S510 of FIG. 5)—a real-time clock (RTC) may wake-up and a latch of the battery management system (BMS) may be activated (see S520 of FIG. 5). Each of the cell monitoring units 120-1, 120-2, . . . , 120-n may monitor a corresponding (e.g., one) battery modules and transmit battery module information including state of charge (SOC) of the corresponding battery module to the control unit. The control unit 140 may determine a SOC deviation for each of the plurality of battery modules 110-1, 110-2, . . . , 110-n based on the battery module information, and may determine at least one battery module having a large SOC deviation, for example, a deviation exceeding a predetermined SOC deviation threshold. The control unit 140 may store SOC deviation values to determine a cell balancing time. For example, each stored SOC deviation may be a value obtained by subtracting the lowest SOC among the SOCs of the battery cells in each of the plurality of battery modules from the average SOC of the corresponding battery module (see S530 of FIG. 5). The control unit 140 may switch the wireless communication unit, which consumes power of the battery module determined as described above, to an active mode to perform cell balancing through power consumption by the wireless communication units together with passive cell balancing (see S540 of FIG. 5). After the RTC is deactivated (see S550 of FIG. 5), based on the SOC deviation of the corresponding battery module being less than a predetermined SOC deviation threshold (see S560 of FIG. 5), the control unit 140 may stop the cell balancing and shut down the operation of the corresponding wireless communication unit (see S570 of FIG. 5). Otherwise, the control unit 140 may further extend a shutdown time of the corresponding wireless communication unit to additionally perform cell balancing (see S580 of FIG. 5).

As used herein, SOC deviation may refer to a difference between the average SOC of each battery module and a reference SOC value. The reference SOC value may be the lowest cell SOC within the module, an overall SOC average across modules, or a predetermined threshold value. The reference SOC value may vary depending on the system configuration or operating conditions.

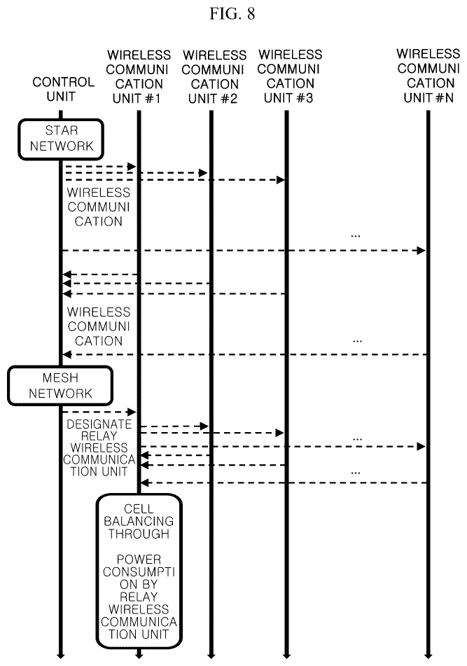

FIG. 7 is a flowchart illustrating a method for operating a battery management system based on activation of an ignition device according to an example embodiment of the present disclosure, and FIG. 8 is a diagram illustrating a method for operating a battery management system based on activation of an ignition device according to an example embodiment of the present disclosure.

Referring to FIGS. 7 and 8, based on activation of the ignition state—for example, a state in which battery-powered electrical loads are activated, such as when the vehicle is in a driving state (see S710 of FIG. 7)—a battery management system may be configured in a centralized star network structure in which the control unit 140 directly transmits and receives information to and from the plurality of cell monitoring units 120-1, 120-2, . . . , 120-n, and may perform passive cell balancing (see S720 of FIG. 7). Each of the cell monitoring units 120-1, 120-2, . . . , 120-n may monitor a corresponding (e.g., one) battery module 110-1, 110-2, . . . , 110-n and transmit battery module information including state of charge (SOC) of the corresponding battery module to the control unit. The control unit may determine a SOC deviation for each of the battery modules based on the battery module information. Based on a SOC deviation for each of the plurality of battery modules exceeding a predetermined deviation threshold (see S730 of FIG. 7), the control unit 140 may be configured to designate the wireless communication unit that consumes power of the battery module having a largest SOC deviation as a relay wireless communication unit (see S740 of FIG. 7), and may configure a mesh network structure in which the wireless communication units, other than the relay wireless communication unit, communicate with the control unit via the designated relay wireless communication unit (see S750 of FIG. 7). Accordingly, cell balancing through power consumption by the relay wireless communication unit may be performed together with the passive cell balancing (see S760 of FIG. 7). Thereafter, based on the ignition device remaining in an activated state (see S770 of FIG. 7), a comparison may be made between a SOC deviation for each of the plurality of battery modules and a predetermined SOC deviation threshold to determine whether to configure a mesh network or a star network (see S730 of FIG. 7).

As used in the present disclosure, the terms “a/an” and “the” include both singular and plural references, unless the context states otherwise. Also, it should be understood that any numerical range recited in the present disclosure is intended to include all sub-ranges subsumed therein (unless indicated otherwise) and accordingly, the disclosed numeral ranges include individuals value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. Examples described in the present disclosure or the terms indicative thereof (“for example”, “such as”) are to describe the present disclosure in greater detail. Therefore, it should be understood that the scope of the present disclosure is not limited to the example embodiments described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example embodiments described above, and rather intended to include the following appended claims, and modifications, equivalents, and alternatives falling within the spirit and scope of the following claims.

The present disclosure described as above is not limited by the aspects described herein and the accompanying drawings. It should be apparent to those skilled in the art that various substitutions, changes and modifications which are not exemplified herein but are still within the spirit and scope of the present disclosure may be made. Therefore, the scope of the present disclosure is provided by the detailed description and also by the claims and their equivalents, and variations within the scope of the claims and their equivalents are to be construed as being included in the present disclosure.

What is claimed is:

1. A battery management system comprising:
a plurality of battery modules, each battery module comprising a plurality of battery cells;
a plurality of cell monitoring units, each cell monitoring unit configured to monitor a corresponding battery module of the plurality of battery modules and generate battery module information for the corresponding battery module, the battery module information comprising state of charge (SOC) information of the corresponding battery module;
a plurality of wireless communication units, each wireless communication unit provided in a corresponding cell monitoring unit of the plurality of cell monitoring units and configured to support wireless communication by consuming power of the corresponding battery module monitored by the corresponding cell monitoring unit; and
a control unit configured to control at least one of the plurality of cell monitoring units and at least one corresponding wireless communication unit based on the battery module information,
wherein the control unit is configured to control at least one wireless communication unit corresponding to at least one battery module, wherein the wireless communication unit consumes power of the battery module to perform cell balancing for the battery module.

2. The battery management system of claim 1, wherein the control unit is configured to determine at least one battery module of the plurality of battery modules with a SOC deviation that exceeds a predetermined SOC deviation threshold based on a SOC deviation for each of the plurality of battery modules.

3. The battery management system of claim 2, wherein the battery module information comprises SOC information of each of the plurality of battery cells included in each of the plurality of battery modules.

4. The battery management system of claim 3, wherein the control unit is configured to determine a duration of the cell balancing based on the SOC deviation of each of the plurality of battery cells included in each determined battery module.

5. The battery management system of claim 1, wherein the control unit is configured to extend a shutdown time of each of the wireless communication units of the plurality of the wireless communication units corresponding to the at least one battery module based on deactivation of an ignition device and perform the cell balancing.

6. The battery management system of claim 1, wherein the control unit is configured to switch each wireless communication unit corresponding to each of the battery modules from a real-time clock (RTC) wake-up state to an active state based on deactivation of an ignition device and perform the cell balancing.

7. The battery management system of claim 1, wherein the control unit is configured to designate a first wireless communication unit as a relay wireless communication unit based on activation of an ignition device.

8. The battery management system of claim 7, wherein the first wireless communication unit consumes power of a first battery module having a largest SOC deviation of the plurality of battery modules.

9. The battery management system of claim 8, wherein the control unit is configured to construct a mesh network in which the plurality of wireless communication units, other than the relay wireless communication unit, communicate with the control unit via the relay wireless communication unit and perform cell balancing.

10. A method for operating a battery management system, the method comprising:
by each of a plurality of cell monitoring units, monitoring a corresponding battery module of a plurality of battery modules and generating battery module information for the corresponding battery module, the battery module information comprising state of charge (SOC) information of the corresponding battery module;
by a plurality of wireless communication units, each wireless communication unit is provided in a corresponding cell monitoring unit of the plurality of cell monitoring units, performing wireless communication by consuming power of the corresponding battery module monitored by the corresponding cell monitoring unit; and
by a control unit configured to control at least one of the plurality of cell monitoring units and a corresponding wireless communication unit based on the battery module information, controlling at least one wireless communication unit corresponding to at least one battery module such that the wireless communication unit consumes power of the battery module, thereby performing cell balancing for the battery module.

11. The method of claim 10, wherein the controlling comprises determining at least one battery module having a SOC deviation that exceeds a predetermined SOC deviation threshold based on a SOC deviation for each of the plurality of battery modules.

12. The method of claim 11, wherein the battery module information comprises SOC information of each of a plurality of battery cells included in each of the plurality of battery modules.

13. The method of claim 12, wherein the controlling further comprises determining a duration of the cell balancing based on SOC deviations of the plurality of battery cells included in each determined battery module.

14. The method of claim 10, wherein the controlling comprises extending a shutdown time of the wireless communication units corresponding to the at least one battery module based on deactivation of an ignition device and performing the cell balancing.

15. The method of claim 10, wherein the controlling comprises switching each wireless communication unit corresponding to each of the plurality of battery modules from a real-time clock (RTC) wake-up state to an active state.

16. The method of claim 15, wherein switching the RTC wake-up state to the active state is based on deactivation of an ignition device and performing the cell balancing.

17. The method of claim 10, wherein the controlling comprises designating a first wireless communication unit as a relay wireless communication unit.

18. The method of claim 17, wherein the first wireless communication unit consumes power of a first battery module having a greatest SOC deviation of the plurality of battery modules.

19. The method of claim 18, wherein the controlling further comprises constructing a mesh network in which the plurality of wireless communication units, other than the relay wireless communication unit, communicate with the control unit via the relay wireless communication unit.

20. The method of claim 19, further comprises performing cell balancing.
